(19) United States
(12) Patent Application Publication
(10) Pub. No.: US 2007/0085143 A1
(43) Pub. Date: Apr. 19, 2007

(54) Semiconductor structure for draining an overvoltage pulse, and method for manufacturing same

(75) Inventors: Bernd Eisener, Hohenbrunn (DE); Hubert Werthmann, Muenchen (DE)

Correspondence Address: Maginot, Moore & Beck;Chase Tower, Suite 3250, 111 Monument Circle, Indianapolis, IN, 46204, US

(73) Assignee: Infineon Technologies AG, Munich (DE)

(21) Appl. No.: 11/540,489

(22) Filed: Sep. 29, 2006

(30) Foreign Application Priority Data
Sep. 30, 2005 (DE) 10 2005 047 000.9

(51) Int. Cl. H01L 23/62

(52) U.S. Cl. 257/361

(57) ABSTRACT

A semiconductor structure for draining an overvoltage pulse comprises a first semiconductor region having a first doping type and a semiconductor layer arranged adjacent the first semiconductor region. The semiconductor layer includes an isolation structure configured to electrically isolate a second semiconductor region from a surrounding region. The second semiconductor region has a second doping type. A third semiconductor region having the first doping type is arranged adjacent the second semiconductor region and is disposed within an area limited by the isolation structure. A first contacting structure is configured to provide an electrical contact with the first semiconductor region, and a second contacting structure is configured to provide an electrical contact with the third semiconductor region. The first and second semiconductor regions are more highly doped than the second semiconductor region.

### CROSS-REFERENCE TO RELATED APPLICATIONS

This application claims priority from German Patent Application No. 102005047000.9, which was filed on Sep. 30, 2005, and is incorporated herein by reference in its entirety.

### FIELD OF THE INVENTION

The present invention generally relates to a semiconductor structure for draining an overvoltage pulse and to a method for manufacturing same, specifically to a vertical anti-serial protection element against electrostatic discharges (ESD protection element).

### BACKGROUND

On the tide of miniaturization in the field of integrated circuit technology, the last few years have shown that electrostatic discharges (ESD) represent an increasing threat since not only are they able to temporarily interfere with proper functioning of a highly integrated circuit, but rather are able to permanently and irreversibly destroy the highly integrated circuit. Therefore, the protection of integrated circuits, but also of sensitive discrete semiconductor devices, such as MOS field-effect transistors, is becoming increasingly important.

For example, with mobile telephones, the connections of integrated circuits (ICs) with plug contacts must be protected from electrostatic discharges (in short: ESD) by means of ESD protection element s. The requirements made in this context are nowadays generally regulated in accordance with the IEC 61000-4-2 norm. In accordance with the norm mentioned, an ESD protection element must withstand a 15 kV contact discharge pulse without switching, and the amount of any clamping voltage which may occur in the process must be small enough for an integrated circuit (IC) coupled to the ESD protection element not to be damaged.

Since, in addition, the frequencies of the signals passing, via the ESD protection element, from an external contact to the integrated circuit (IC) or vice versa are not infrequently within the range of several 100 MHz and may range up to about 2 GHz in the event of signals which are fed to a transmitting aerial or are received by a receiving aerial, a capacitance of the ESD element or ESD protection element must be as low as possible.

In accordance with the prior art, various arrangements have been known by means of which one has attempted to meet the above requirements in various ways. For example, a simple np diode which blocks a positive direct voltage, or positive bias, with respect to ground may be used as an ESD protection element. In other words, an n-p semiconductor junction which may be generated in a substrate by diffusion, for example, may be used to drain electrostatic discharges. Specifically, such a semiconductor junction will block when the voltage or potential difference applied thereto is smaller than a breakdown voltage and when the n-p semiconductor junction is reverse biased. On the other hand, if a reverse voltage higher than the breakdown voltage is applied to the n-p semiconductor junction, the n-p semiconductor junction may become conducting, for example due to an avalanche breakdown, whereby an electrostatic discharge is drained which generates a voltage higher than the breakdown voltage.

The use of an np diode as an ESD protection element has the advantage that simple technology may be used for manufacturing the np diode. Low manufacturing cost result. However, an essential disadvantage of using an np diode is that an np diode has a high capacitance. Here, the high capacitance of the np diode has disadvantageous effects on a frequency response and/or a pulse response of the ESD protection element in transmitting a useful signal.

In addition, it is possible to connect two np diodes in anti-series across the substrate. With such an arrangement, it is indeed possible to decrease the capacitance of the ESD protection element, but one has to accept that the common floating base of several signal lines, i.e. the substrate, may lead to undesirable crosstalk between the signal lines.

In addition, a lateral pnp transistor with a floating base (a base which is not specified to a potential predefined externally) may also be used as the ESD protection element. A lateral pnp transistor with a floating base is employed, e.g., in the BGF 100 microphone filter by Infineon. The advantage of using a lateral pnp transistor as the ESD protection element is the fact that the lateral pnp transistor may be readily integrated. In addition, a lateral pnp transistor exhibits a doubly blocking function for both polarities of signal line versus ground. Such a doubly rectifying function function is required for some applications. In addition, current conduction is effected essentially by majority charge carriers in a lateral pnp transistor. A heavy-duty resistance as is measured, for example, with a transmission line pulse (TLP) is clearly lower than with a simple np diode. A disadvantage in using a lateral pnp transistor with a floating base is the high capacitance exhibited by such a lateral pnp transistor with a floating base. In addition, a structure having a lateral pnp transistor entails a substantial spatial requirement when using single-sheet metallization, since the major portion of the area of the protective element, i.e. of the lateral pnp transistor, cannot be placed underneath a contact pad.

### SUMMARY

Against the background of the prior art mentioned, it is the object of the present invention to provide a semiconductor structure for draining an overvoltage pulse as well as a method for manufacturing same, the semiconductor structure exhibiting, in comparison to conventional arrangements, reduced capacitance while having comparable dielectric strength.

In accordance with a first aspect, the invention provides a semiconductor structure for draining an overvoltage pulse comprising a first semiconductor region having a first doping type and a semiconductor layer arranged adjacent the first semiconductor region. The semiconductor layer includes an isolation structure configured to electrically isolate a second semiconductor region from a surrounding region. The second semiconductor region has a second doping type. A third semiconductor region having the first doping type is arranged adjacent the second semiconductor region and is disposed within an area limited by the isolation structure. A first contacting structure is configured to provide an electrical contact with the first semiconductor region, and a second contacting structure is configured to provide an electrical contact with the third semiconductor region. The first and second semiconductor regions are more highly doped than the second semiconductor region.

In accordance with a second aspect, the invention provides a method for manufacturing a semiconductor structure, the method including the steps of: providing a first semiconductor region having a first doping type; applying a semiconductor layer onto a surface of the first semiconductor region; introducing an isolation structure introduced into the semiconductor layer to electrically isolate a second semiconductor region from a region of the semiconductor layer which surrounds the second semiconductor region, the second semiconductor region having a second doping type which is different from the first doping type; providing a third semiconductor region, having the first doping type, adjacently on the second semiconductor region; providing a first contacting structure designed to establish an electrical contact with the first semiconductor region; and providing a second contacting structure designed to establish an electrical contact with the third semiconductor region, the third semiconductor region adjoining the semiconductor layer only within an area limited by the isolation structure; the first semiconductor region being more highly doped than the second semiconductor region; the third semiconductor region being more highly doped than the second semiconductor region.

### BRIEF DESCRIPTION OF THE DRAWINGS

These and other objects and features of the present invention will become clear from the following description taken in conjunction with the accompanying drawing, in which:

FIG. 1 shows a cross section through an inventive semiconductor structure in accordance with a first embodiment of the present invention;

FIG. 2 shows a cross section through an inventive semiconductor structure in accordance with a second embodiment of the present invention;

FIG. 3 shows a graphical representation of manufacturing masks for manufacturing the inventive semiconductor structure in accordance with the second embodiment of the present invention;

FIG. 4 shows a doping profile of the inventive semiconductor structure in accordance with the second embodiment of the present invention; and

FIG. 5 shows a top view of an inventive protection circuit having an inventive semiconductor structure in accordance with the second embodiment of the present invention; and

FIG. 6 shows a flow chart of an inventive manufacturing method for manufacturing an inventive semiconductor structure.

### DETAILED DESCRIPTION

The present invention provides a semiconductor structure for draining an overvoltage pulse, having a first semiconductor region having a first doping type, a semiconductor layer arranged adjacently on the first semiconductor region, an isolation structure introduced into the semiconductor layer to electrically isolate a second semiconductor region from a region of the semiconductor layer which surrounds the second semiconductor region, the second semiconductor region having a second doping type which is different from the first doping type, and a third semiconductor region having the first doping type and being arranged adjacently on the second semiconductor region. An inventive semiconductor structure further includes a first contacting structure designed to establish an electrical contact with the first semiconductor region, as well as a second contacting structure designed to establish an electrical contact with the third semiconductor region. In addition, in the inventive semiconductor structure, the third semiconductor region adjoins the semiconductor layer only within an area limited by the isolation structure. Also, in the inventive semiconductor structure, the first semiconductor region is more highly doped than the second semiconductor region, and the third semiconductor region is also more highly doped than the second semiconductor region.

In addition, the present invention provides a method for manufacturing a respective semiconductor structure.

It is the core idea of the present invention that it is advantageous to use a vertical structure which consists of three regions, arranged one above the other, of alternately different doping types, for draining an overvoltage pulse, since in this manner, a particularly good ratio of dielectric strength and capacitance may be achieved. An inventive semiconductor structure may further be manufactured by means of a particularly efficient manufacturing method.

In addition, one has recognized that the alternate use of semiconductor regions having high and/or low dopings, respectively, results in a semiconductor structure having a particularly low capacitance and, at the same time, a well-defined, sufficiently low breakdown voltage and high absolute dielectric strength.

The use of an isolation structure for demarcating the second semiconductor region from a region of the semiconductor layer which surrounds the second semiconductor region further allows to achieve, while using a low-cost and advantageous technology for applying semiconductor layers, that a contact pad be exactly defined, in spatial terms, between the first and second semiconductor regions.

In addition, the use of the isolation structure introduced into the semiconductor layer may ensure that in the second semiconductor region, an essentially vertical current flow predominates in a direction perpendicular to a contact pad between the first semiconductor region and the semiconductor layer. Such an essentially vertical current flow here results in a current density which is distributed in an essentially even manner across the contact pad between the first semiconductor region and the semiconductor layer. Thus, well-defined properties of the inventive semiconductor structure result which are insensitive toward manufacturing-induced variations. In addition, an even distribution of the current density also results in an equally even distribution of the power loss, whereby the inventive semiconductor structure has a particularly high dielectric strength as compared to conventional ESD protection elements.

In addition, due to the fact that the third semiconductor region adjoins the semiconductor layer only within the area limited by the isolation structure, a parasitic stray capacitance between the first and third semiconductor regions may be minimized, so that the overall capacitance of the inventive semiconductor arrangement is dominated essentially by the semiconductor junctions. Thus, a particularly good ratio of dielectric strength and capacitance results for the inventive semiconductor structure.

The layer-like structure of the second semiconductor region further ensures that electric flux lines one merely parallel to one other in the second semiconductor region, whereby a concentration of the electric field at individual locations may be avoided, which in turn leads to an improvement of the dielectric strength in comparison with conventional ESD protection elements.

Thus, the inventive semiconductor structure entails a series of essential advantages over conventional semiconductor structures, said advantages being briefly summarized once again below. The inventive semiconductor structure has a particularly low capacitance as compared to conventional ESD protection elements. This results, at least in part, from the fact that the inventive semiconductor structure includes two semiconductor junctions (pn junctions or np junctions) connected in anti-series, whereas only one semiconductor junction is present in ESD protection elements with a simple diode structure.

A current distribution at the pn junctions is very even due to the inventive structure, which results in a particularly high absolute dielectric strength of the inventive semiconductor structure. Therefore, the inventive semiconductor structure is particularly insensitive toward voltage peaks, so that a destruction of the inventive semiconductor structure is not to be expected in a normal operating environment. The even current distribution, specifically, prevents excessive local warming in individual limited areas, as may occur in the event of a highly inhomogeneous current distribution, and at the same time contributes to the fact that the variation of the properties of the inventive semiconductor structure due to manufacturing-induced tolerances is less pronounced.

In addition, it shall be noted that with the inventive semiconductor structure, charge transfer is essentially effected by the majority charge carriers, so that the inventive semiconductor structure does not exhibit a high level of temperature dependence, and further exhibits low heavy-duty resistance.

In addition, a particularly advantageous spatial demarcation of the second semiconductor region from a surrounding semiconductor region is ensured, in the inventive semiconductor structure, by the isolation structure introduced into the semiconductor layer. The introduction of the isolation structure into the semiconductor layer is possible in a technologically advantageous manner without giving rise to semiconductor boundary areas with open bonds which might compromise a dielectric strength.

Incidentally, the current flow in the semiconductor layer occurs essentially perpendicularly to the surface of the semiconductor layer, so that surface-induced interference effects, for example a surface recombination or capturing of charge carriers, may be avoided or have only minor effects. In addition, for draining an overvoltage it is essential that with the inventive semiconductor structure, electrical field strengths tangential to contact pads between various semiconductor regions as well as at boundary areas between semiconductor regions and isolation structures may be kept low, whereby a leakage current along a surface and/or a breakdown at a surface, which sometimes occur with conventional ESD protection elements, may be avoided.

In addition, it shall be pointed out that the inventive semiconductor structure may be realized at low technological expense within the framework of standard technology with single-sheet metallization and at comparatively low space requirements. Thereby, the manufacturing cost of the inventive semiconductor structure may be drastically reduced as compared to the manufacturing cost which arises in the manufacturing of conventional ESD protection elements.

In a further preferred embodiment, the geometry of the inventive semiconductor structure as well as the doping of the semiconductor regions occurring therein are designed such that the inventive semiconductor structure forms a vertical bipolar transistor with a floating base region. Here, for example, the first semiconductor region may represent a collector region of the vertical bipolar transistor, whereas the second semiconductor region represents a base region of the vertical bipolar transistor, and the third semiconductor region represents an emitter region of the vertical bipolar transistor. In reverse terms, however, it is also possible for the first semiconductor region to represent an emitter region of the vertical bipolar transistor, while the third semiconductor region represents a collector region of the vertical bipolar transistor.

Specifically, one has found that the inventive semiconductor structure is particularly suitable for draining overvoltage pulses when the effect of a breakdown of a semiconductor junction between the first semiconductor region and the second semiconductor region or between the second semiconductor region and the third semiconductor region is combined with a switching behavior of a bipolar transistor. In other words, in the event of a breakdown, an avalanche breakdown and switching-on of a bipolar transistor have a combined effect, which results in a particularly low heavy-duty resistance of the inventive semiconductor structure in the event of a breakdown.

Incidentally, it shall be noted that the mode of operation of the inventive semiconductor structure as a vertical bipolar transistor may be achieved, for example, in that a thickness of the second semiconductor region is selected to be sufficiently small as compared to a diffusion length of minority charge carriers in the second semiconductor region (e.g. is selected to be at least smaller than the diffusion length of the minority charge carriers). In addition, it shall be noted that the doping of the second semiconductor region is preferably selected to be smaller than 10¹⁸ cm⁻³ so as to guarantee a sufficiently high level of functionality of the vertical bipolar transistor. In addition, it is preferred for at least one doping of the first semiconductor region or of the third semiconductor region to be higher than the doping of the second semiconductor region so as to define, by means of the high level of doping, an emitter region in the first or second semiconductor regions.

In normal operation, i.e. when there is no overvoltage pulse, except for parasitic current flows through semiconductor junctions, the second semiconductor region is preferably fully isolated electrically from its surroundings. In other words, a potential of the second semiconductor region is not specified to a value which is or may be predefined externally. On the one hand, this contributes to a particularly low capacitance of the first semiconductor structure, since, as is known, a potential, predefined externally, of the second semiconductor region would correspond to a short circuit of one of the capacitances between the first and second semiconductor regions or between the second and third semiconductor regions. Also, due to the fact that the second semiconductor region floats, what results is a particularly advantageous breakdown behavior at a well-defined breakdown voltage.

In a further preferred embodiment, the second semiconductor region is designed such that the second semiconductor region is electrically isolated from all the regions surrounding the second semiconductor region if a voltage between the first and second contacting structures is smaller than a predefined breakdown voltage. Specifically, it is preferred for the first and second contacting structures to be the only contacting structures of the inventive semiconductor device, and for a current flow through the inventive semiconductor structure to be inhibited as long as the voltage between the first and second contacting structures is smaller than the predefined breakdown voltage. In this case, the second semiconductor region, which is located between the first and third semiconductor regions, is electrically isolated and thus allows no current flow. Thus, the inventive semiconductor structure represents no load in terms of direct current if the voltage between the first and second contacting structures is smaller than the breakdown voltage. However, it shall be pointed out here that the expression “electrically isolated” obviously does not exclude the presence of dielectric displacement currents in the event of an alternating voltage being applied between the first and second contacting structures.

In addition, it is preferred for the semiconductor structure to be designed such that an avalanche breakdown occurs in a space charge region between the first and second semiconductor regions or in a space charge region between the second and third space charge regions if a voltage between the first and second contacting structures is larger than the predefined breakdown voltage. In this case, a well-controlled and non-destructive breakdown of the semiconductor structure will occur, so that the semiconductor structure may drain the overvoltage pulse by a current flow between the first and second contacting structures and through the second semiconductor region. In connection with the inventive semiconductor structure, which ensures even distribution of the electric field across the space charge regions of the second semiconductor region, an avalanche breakdown here leads to a well-controlled and reproducible dissipation of the overvoltage pulse. In addition, it shall be pointed out that the inventive structure has a breakdown voltage which may be precisely defined and below which a current flow is effectively inhibited, and above which a current flow is effected due an avalanche breakdown. Here, the breakdown voltage may be adjusted by a suitable doping profile and/or by using suitable dopants. Annealing operations which may be performed in a production of the semiconductor structure, as well as a quality of surfaces have an effect on the onset of an avalanche breakdown.

In addition, the inventive semiconductor structure is preferably designed to conduct a current between the first and second contacting structures through the second semiconductor region without the semiconductor structure being destroyed if a voltage between the first and second contacting structures is larger than the predefined breakdown voltage, and smaller than a maximum tolerable voltage. The maximum tolerable voltage here is determined, for example, by thicknesses of the semiconductor regions as well as by the nature of boundary areas, and describes a voltage at which a destructive breakdown of the inventive semiconductor structure will occur.

In a preferred embodiment, the inventive semiconductor structure is optimized such that the maximum tolerable voltage is higher than 5 kV, but preferably higher than 10 kV. It shall be noted here that the maximum tolerable voltage may naturally be applied to the inventive semiconductor structure for a very short time only before the inventive semiconductor structure drains a respective overvoltage pulse by a current flow between the first and second contacting structures.

In addition, it is preferred for the isolation structure to be designed to electrically isolate, by a space-charge region, the second semiconductor region from that region of the semiconductor layer which surrounds the second semiconductor region. Isolating the second semiconductor region by a space-charge region here is advantageous, since a space-charge region requires no junction between two different materials, which is typically associated with an interference with a grid structure. Rather, a space-charge region may be achieved merely by areas of the single semiconductor material which are doped differently. Thus, it may be achieved, due to the inventive isolation of the second semiconductor region from that region of the semiconductor layer which surrounds the second semiconductor region, that no material boundary area occurs at the sides of the second semiconductor region. This results in a particularly high dielectric strength of the inventive semiconductor structure.

In the further preferred embodiment, the isolation structure is a trench which is introduced into the semiconductor layer, is filled with an electrically isolating material and runs through the semiconductor layer from a first surface, at which the semiconductor layer borders on the first semiconductor region, to a second surface of the semiconductor layer, which is opposite the first surface. Such a design has the advantage that the isolation structure entails a particularly good isolation structure property. In addition, a capacitance formed by the isolation structure described is independent of a voltage applied between the first and second contacting structures and is also very low. In addition, the inventive isolation structure described exhibits a particularly low parasitic current flow. In addition, the dielectric strength may be set to be very high by means of selecting a suitable isolating material.

In a further preferred embodiment, the first contacting structure includes a doped area introduced into the semiconductor layer which contacts the first semiconductor region in a conducting manner, which has the first doping type and which runs through the semiconductor layer from the first surface of the semiconductor layer at which the semiconductor layer contacts the first semiconductor region, to a second surface of the semiconductor layer which is opposite the first surface. In other words, a highly doped and, thus, highly conducting area, which establishes a contact with the first semiconductor region, may be doped into the semiconductor layer. By means of the respective structure, one may achieve, in a manner which is particularly advantageous in technological terms, that both the first and third semiconductor regions may be contacted by the same surface of the semiconductor. In addition, it shall be pointed out that both the doped area introduced into the semiconductor layer which has just been described and which is part of the first contacting structure, and an area which serves to isolate and/or demarcate the second semiconductor region may be manufactured in one single technological step. In other words, an isolation structure doped into the semiconductor layer, and the area which is associated with the first contacting structure and has been introduced into the semiconductor layer may have the same doping, which enables particularly advantageous manufacturing.

In a further preferred embodiment, the second semiconductor region is designed to exhibit essentially the shape of a cylinder disc, wherein a height is smaller than a diameter, wherein disturbances of the ideal cylinder-shaped geometry at the contact pad between the second and third semiconductor regions are neglected. It is preferred for the thickness of the second semiconductor region, which corresponds to a height of the cylinder disc, to be smaller than one tenth of a diameter of the second semiconductor region. A cylinder-shaped geometry has proven particularly advantageous, since a particularly even distribution of the current flow may be achieved thereby. In addition, the distribution of the electrical field strength is also even, which results in a particularly high dielectric strength of the inventive semiconductor structure for draining an overvoltage pulse.

In addition, it is preferred for the semiconductor layer to be a layer which is applied in an epitactic manner onto the first semiconductor region. When manufacturing an epitactic layer, specifically, a layer thickness may be set in a particularly precise manner, it being possible to simultaneously specify a predefined doping of the semiconductor layer. In addition, a layer applied in an epitactic manner typically comprises a very good semiconductor structure with a low number of defects, which in turn contributes to the high dielectric strength of the inventive semiconductor structure.

In addition, it is preferred for the geometry and the utilized doping of the inventive semiconductor structure to be adjusted so as to obtain a dielectric strength of at least 5 kV, but preferably at least 10 kV. To this end, for example, a thickness of the first semiconductor region (measured perpendicularly to the contact pad between the first semiconductor region and the semiconductor layer), a thickness of the second semiconductor region (measured perpendicularly to the contact pad between the first semiconductor region and the semiconductor layer) as well as a thickness of the third semiconductor region (measured perpendicularly to the contact pad between the first semiconductor region and the semiconductor layer) are set accordingly. In addition, the dopings of the three semiconductor regions are preferably selected to achieve a dielectric strength of at least 5 kV. Thus, the inventive semiconductor structure may meet the requirements, in accordance with the norm, for draining an overvoltage pulse.

In a further preferred embodiment, the doping of the second semiconductor region is selected in a range between 10¹⁶ cm⁻³ and 10¹⁸ cm⁻³. Such a doping is particularly suitable to operate the semiconductor structure as a bipolar transistor, the second semiconductor region representing a base region of the bipolar transistor. Setting the doping of the second semiconductor region accordingly contributes to obtaining a sufficient and/or advantageous charge-carrier life span of minority carriers in the second semiconductor region and, consequently, also a sufficiently large diffusion length. Specifically, as has already been mentioned above, it is particularly advantageous to operate the inventive semiconductor structure as a bipolar transistor with a floating base.

In addition, it is preferred to select the doping of the first semiconductor region having an (effective) dopant concentration (donor concentration or acceptor concentration, respectively) from a range from 10¹⁸ cm⁻³ to 10²⁰ cm⁻³. Here, the doping of the third semiconductor region may also preferably be selected from a range from 10¹⁸ cm⁻³ to 10²¹ cm⁻³, preferably a doping of the third semiconductor region being higher than a doping of the first semiconductor region. Thereby it may be achieved that the inventive semiconductor structure may act as a bipolar transistor having as low a heavy-duty resistance as possible. Here, the third semiconductor region preferably represents the emitter. However, the first semiconductor region preferably also has a similarly high doping as the third semiconductor region and thus may, depending on the polarity of the overvoltage pulse applied between the first and third contacting structures, also become operative as an emitter. In other words, unlike with a conventional bipolar transistor, in the inventive semiconductor structure, both the first and third semiconductor regions are very highly doped, so that preferably no unique definition of an emitter region and a collector region is given. Rather, both the first and third semiconductor regions may both act as an emitter region and as a collector region, respectively. In addition, it shall be noted that a particularly high doping of the third semiconductor region ensures that the third semiconductor region may be contacted directly.

In addition, the second semiconductor region has a thickness between 0.5 μm and 5 μm in the further preferred embodiment. Such a design is advantageous, since the second semiconductor region may then act as a floating base region of a bipolar transistor. Specifically, one has found that with a respective thickness, there is an optimum trade-off between the dielectric strength of the inventive semiconductor structure and a heavy-duty resistance in draining an overvoltage pulse.

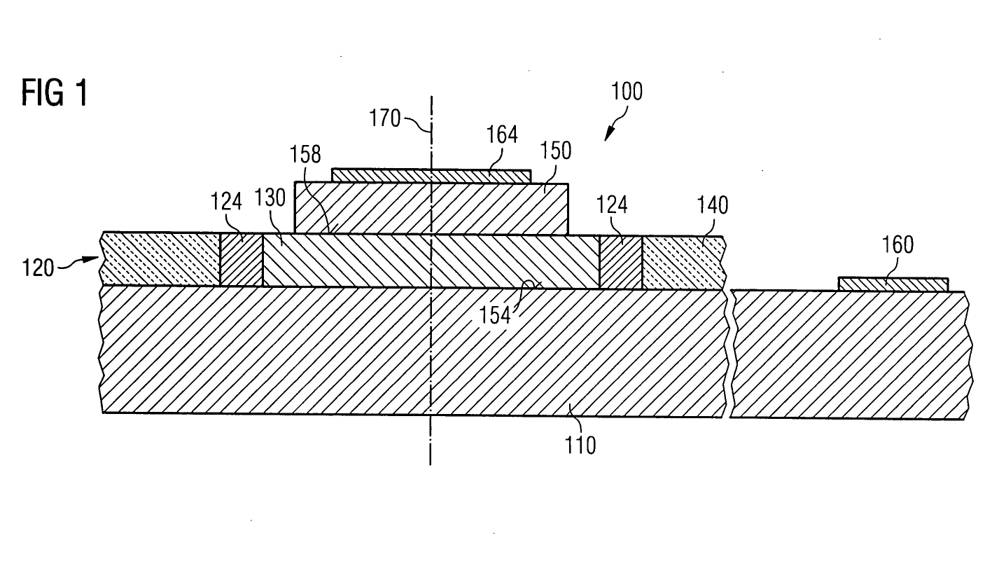

Now referring to the figures, FIG. 1 shows a cross section through an inventive semiconductor structure in accordance with a first embodiment of the present invention. The cross section of FIG. 1 is designated by 100 in its entirety. The inventive semiconductor structure 100 includes a first semiconductor region 110 which has a semiconductor layer 120 deposited thereon. The semiconductor layer 120 has an isolation structure 124 introduced therein, which isolates a second semiconductor region 130, which is part of the semiconductor layer 120, from a region, surrounding the second semiconductor region 130, of the second semiconductor layer 120. The region of the semiconductor layer 120 which surrounds the second semiconductor region 130 is designated by 140. In addition, a third semiconductor region 150 is arranged on the second semiconductor region 130. In other words, the second semiconductor region 130 contacts, at a first contact pad 154, the first semiconductor region 110, and contacts, at a second contact pad 158, the third semiconductor region 150, the first contact pad 154 being opposite the second contact pad 158.

In addition, the inventive semiconductor structure 100 includes a first contacting structure 160 designed to establish an electrical contact with the first semiconductor region 110. In addition, a second contacting structure 164 is arranged at the third semiconductor region 150 such that it establishes an electrical contact with the third semiconductor region 150.

It shall also be pointed out that the inventive semiconductor structure, except for the first contacting structure 160, is preferably rotationally symmetric in relation to a symmetry axis 170.

In addition, it is to be stated that the first semiconductor region 110 and the third semiconductor region 150 preferably have a first doping type, whereas the second semiconductor region 130 has a second doping type different from the first doping type. For example, the first semiconductor region 110 and the third semiconductor region 150 are preferably p-doped, whereas the second semiconductor region 120 is n-doped. The region 140 which surrounds the second semiconductor region 130 further preferably has the same doping as the second semiconductor region. In addition, it shall be pointed out that the doping of the first semiconductor region 110 is preferably higher than the doping of the second semiconductor region 130. Similarly, the doping of the third semiconductor region 150 is preferably higher than the doping of the second semiconductor region 130.

In addition, it shall be noted that third semiconductor region 150 is arranged such that it contacts semiconductor layer 120 only within the area limited by isolation structure 124, so that third semiconductor region 150 just does not contact the region 140 surrounding the second semiconductor region 130.

On the basis of the structural description, a more detailed explanation will be given below of the mode of operation of the inventive semiconductor structure 100. One operates on the assumption that between first contacting structure 160 and second contacting structure 164, a voltage is applied which is smaller, in normal operation, than a breakdown voltage of semiconductor structure 100, and is larger, in the event of an overvoltage, than a breakdown voltage of semiconductor structure 100.

The geometry parameters of semiconductor structure 100 are preferably selected such that semiconductor structure 100 forms a bipolar transistor with a floating base. This may be achieved by suitable selection of the thickness of the second semiconductor region 130 as well as by suitable selection of the dopings. In this case, second semiconductor region 130 forms a floating base region of the bipolar transistor, i.e. a base region which is not specified externally with regard to the potential. In addition, the first semiconductor region forms a collector region or an emitter region of the bipolar transistor, depending on the polarity of the voltage applied between first contacting structure 160 and second contacting structure 164. Similarly, third semiconductor region 150 forms a collector region or an emitter region of the bipolar transistor as a function of the polarity of the voltage applied between first contacting structure 160 and second contacting structure 164. Thus, a p-n semiconductor junction forms at the first contact pad 154 between first semiconductor region 110 and second semiconductor region 130. In addition, an n-p semiconductor junction forms at second contact pad 158 between first semiconductor region 130 and third semiconductor region 150. The p-n semiconductor junction at first contact pad 154 is connected in anti-series with the n-p semiconductor junction at the second contact pad 158.

Thus, there is at least one blocked semiconductor junction, respectively, between first contacting structure 160 and second contacting structure 164 as long as the voltage applied between first contacting structure 160 and second contacting structure 164 is smaller than the breakdown voltage. Thus, no current, or, at the most, a negligible cut-off current, may flow between first contacting structure 160 and second contacting structure 164. Here, the potential of second semiconductor region 130 follows the potential of first semiconductor region 110 or of third semiconductor region 150, depending on the sign exhibited by the voltage applied between first contacting structure 160 and second contacting structure 164. However, no current will flow in a stationary case, since as is known, either the p-n semiconductor junction at first contact pad 154 is blocked, or n-p semiconductor junction at second contact pad 158 is blocked. However, if the amount of voltage applied between first contacting structure 160 and second contacting structure 164 is increased to exceed the breakdown voltage of the inventive semiconductor structure, an avalanche breakdown will occur at the blocked semiconductor junction at first contact pad 154 or at second contact pad 158 (depending on the polarity of the voltage applied). Thus, a current flows between first contacting structure 160 and second contacting structure 164, by means of which current an overvoltage pulse between first contacting structure 160 and second contacting structure 164 may be drained.

One operates on the assumption, by way of example, that first semiconductor region 110 and third semiconductor region 150 are p-doped, whereas second semiconductor region 130 is n-doped, and that the geometries of the inventive semiconductor structure as well as the doping quantities are designed such that the inventive semiconductor structure forms a p-n-p transistor with a floating base region formed by second semiconductor region 130. Also, it is assumed here that at second contacting structure 164, a voltage is applied which is positive as compared with first contacting structure 160 and which, for the time being, is smaller than the breakdown voltage. In this case, third semiconductor region 150 represents an emitter region of the pnp bipolar transistor, whereas first semiconductor region 110 forms a collector region of the pnp bipolar transistor. A semiconductor junction between third semiconductor region 150 and second semiconductor region 130 is forward-biased, whereas a semiconductor junction between second semiconductor region 130 and first semiconductor region 110 is reverse-biased. A current flow between second contacting structure 164 and first contacting structure 160 here is minimal. It shall also be pointed out that in the case described, the potential of second semiconductor region 130 differs from the potential of third semiconductor region 150 only by a diffusion potential of the semiconductor junction between third semiconductor region 150 and second semiconductor region 130.

However, if the voltage applied between second contacting structure 164 and first contacting structure 160 is increased to exceed the breakdown voltage of the semiconductor junction between second semiconductor region 130 and first semiconductor region 110, an avalanche breakdown of the semiconductor junction between second semiconductor region 130 and first semiconductor region 110 will occur. Thus, a current now flows through the semiconductor junction between second semiconductor region 130 and first semiconductor region 110, i.e. through the first contacting pad 154. Thereby, the potential of second semiconductor region 130, i.e. the base potential of the pnp bipolar transistor formed by first semiconductor region 110, second semiconductor region 130 and third semiconductor region 150, is reduced. Thereby, the pnp bipolar transistor is effectively switched on, so that a high level of current may flow between second contacting structure 164 and first contacting structure 160. Therefore, for draining an overvoltage pulse applied between second contacting structure 164 and first contacting structure 160, use is made not only of the breakdown of the semiconductor junction between second semiconductor region 130 and first semiconductor region 110, but also of the switching effect of the bipolar transistor formed by the three semiconductor regions 110, 130, 150.

It shall further be pointed out that a respective effect will result if the polarity of the voltage applied between second contacting structure 164 and first contacting structure 160 is reversed. In this case, first semiconductor region 110 acts as an emitter region of the bipolar transistor, whereas third semiconductor region 150 acts as a collector region of the bipolar transistor. Particularly advantageous properties with regard to the behavior in terms of various polarities of the voltage applied may be achieved if it is ensured that the dopings of first semiconductor region 110 and of third semiconductor region 150 differ by a factor of 10 at the most, with a possibly necessary doping for achieving an ohmic contact between third semiconductor region 150 and second contacting structure 164 being neglected, of course. In other words, it is preferred for a doping of first semiconductor region 110, calculated at a distance of about 0.2 μm from first contact pad 154, to differ from a doping of third semiconductor region 150, at a distance of about 0.2 μm from second contact pad 158, by a factor of 30 at the most, preferably by a factor of 10 at the most. In other words, in the surroundings of first contact pad 154 and second contact pad 158, first semiconductor region 110 and second semiconductor region 150 have similar dopings for the reasons mentioned, the dopings differing by a factor of 10 at the most. This ensures that the inventive semiconductor structure may drain overvoltages, or overvoltage pulses, of positive and negative polarities between second contacting structure 164 and first contacting structure 160 alike.

In addition, it shall be pointed out that the limitation of second semiconductor region 130 by the isolation structure 124 introduced into semiconductor layer 120 entails a particularly advantageous definition of first contact pad 154 between first semiconductor region 110 and second semiconductor region 130. Thus, what may be achieved is that the current density is distributed very evenly across first contact pad 154, which enables a particularly high level of current-carrying capacity of the inventive semiconductor structure 100. For example, there will be no formation of isolated regions with a particularly high level of thermal load, at which the semiconductor structure may be destroyed. Peaks of the electric field strength are also avoided by the inventive geometry, which results in a particularly high dielectric strength of the inventive semiconductor structure 100.

In addition, the inventive semiconductor structure is very compact and requires little surface area in an integrated circuitry. In addition, only a small amount of stray capacitances occur in the inventive semiconductor structure 100, since first semiconductor region 110 and third semiconductor region 150 are always separated by the second semiconductor region, and are not directly adjacent to one another. Rather, the technological expense for manufacturing the inventive semiconductor structure is low, since, for example, the thickness of second semiconductor region 130 is essentially determined by the thickness of semiconconductor layer 120.

It shall also be pointed out that further advantages of the inventive semiconductor structure result from a specific implementation of isolation structure 124. Preferably, isolation structure 124 surrounds second semiconductor region 130 in a circular or ellipse-shaped manner. In addition, isolation structure 124 may preferably be an implanted area having the same doping type as first semiconductor region 110, i.e. a doping type opposite to that of second semiconductor region 130. Thus, a space-charge region which inhibits a lateral current flow in parallel with first contact pad 154 is formed between isolation structure 124 and second semiconductor region 130. In addition, by realizing the isolation structure 124 in the form of a doped area, no border of materials occurs at the edge of second semiconductor region 130. This fact contributes to an increase in the dielectric strength of the inventive semiconductor structure 100.

In addition, the isolation structure 124 may also consist in a trench, filled with an isolator, in semiconductor layer 120. Thereby, a particularly high breakdown strength of isolation structure 124 may be ensured, which is independent of a voltage applied to semiconductor structure 100.

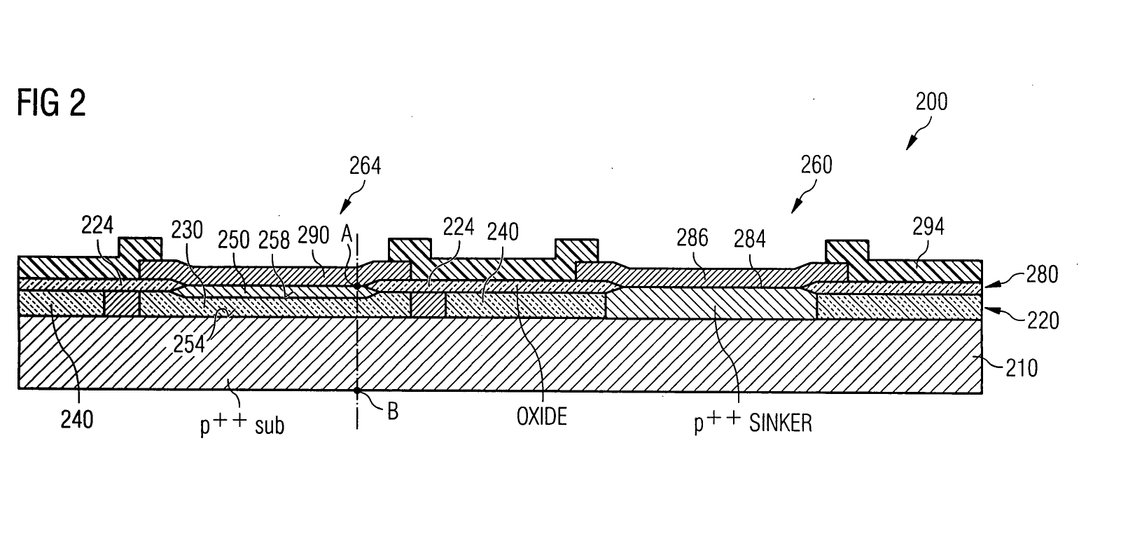

FIG. 2 shows a cross section through an inventive semiconductor structure in accordance with a second embodiment of the present invention. The cross section of FIG. 2 is designated by 200 in its entirety. Here, semiconductor structure 200 includes a first semiconductor region 210 formed by highly p-doped substrate. The highly p-doped substrate is also referred to as “p⁺⁺sub”. A semiconductor layer 220 including several semiconductor regions is arranged on first semiconductor region 210. Semiconductor layer 220 is, for example, a layer which is n-doped and is epitactically deposited onto first semiconductor region 210. An isolation structure 224 which is introduced into semiconductor layer 220 here limits a second semiconductor region 230, which forms part of semiconductor layer 220. Isolation structure 224 is formed, for example, by a highly p-doped area which is introduced into semiconductor layer 220 and encloses second semiconductor region 230 within semiconductor layer 220 in an annular manner.

Second semiconductor region 230 is thus isolated, by isolation structure 224, from a region 240 of semiconductor layer 220 which surrounds second semiconductor region 230. Isolation structure 224 may thus be understood as p⁺⁺ diode border. In addition, a third semiconductor region 250, which is highly p-doped in the embodiment shown (also referred to as p⁺⁺ region), is also doped into second semiconductor region 230. Because of the arrangement described of first semiconductor region 210, of second semiconductor region 230 and of third semiconductor region 250, a first contact pad 254 will thus form between first semiconductor region 210 and second semiconductor region 230, and a second contact pad 258 will form between second semiconductor region 230 and third semiconductor region 250.

Thus, a lower diode is formed on first contact pad 254 between first semiconductor region 210 and second semiconductor region 230. In addition, an upper diode is formed on second contact pad 258 between second semiconductor region 230 and third semiconductor region 250.

In addition, the inventive semiconductor structure comprises a first contacting structure 260 designed to establish an electrical contact with first semiconductor region 210. In addition, a second contacting structure 264 enables to establish an electrical contact with third semiconductor region 250. First contacting structure 260 and second contacting structure 264 will be described in more detail below.

Also, an isolator layer 280 which covers the semiconductor structure toward the top is formed on semiconductor layer 220. Isolator layer 280 comprises only recesses in the area of first contacting structure 260 and of second contacting structure 264. Thus, isolator layer 280 which may, for example, include an oxide, also covers part of an upper surface of second semiconductor region 230 which is not in contact with third semiconductor region 250. The upper surface of second semiconductor region 230 here is that surface which is opposite contact pad 254 between first semiconductor region 210 and second semiconductor region 230. The upper surface of second semiconductor region 230 is therefore completely covered by third semiconductor region 250 and by isolator layer 280.

Thus, second semiconductor region 230 is fully enclosed by first semiconductor region 210, by isolation structure 224, by isolation layer 280 and by third semiconductor region 250. Thus, second semiconductor region 230 comprises no electric connection. In other words, the second semiconductor region floats.

In addition, the inventive semiconductor structure 200 includes a highly doped area 284 diffused, for example, into that region 240 of semiconductor layer 220 which surrounds second semiconductor region 230. Preferably, there is a distance between isolation structure 224 and the highly doped region 284, so that there is a lightly doped region between isolation structure 224 and the highly doped area 284. The highly doped region 284 further runs through semiconductor layer 220 preferably from the contact pad between semiconductor layer 220 and the first semiconductor region to an opposite surface of semiconductor layer 220. In addition, isolation layer 280 has a recess above the highly doped region 284. In addition, a first metallization 286, which forms an electrically conductive contact with the highly doped region 284, is formed above the highly doped region 284. Since the highly doped region 284 has the same doping type as the first semiconductor region 210, i.e. is highly p-doped in the present embodiment (i.e. p⁺⁺ doped), the highly doped region 284 introduced into semiconductor layer 220 is suited to establish an electrical contact between first semiconductor region 210 and first metallization 286. Of course, other common measures may be taken in the area of first contacting structure 260 so as to establish a low-resistance electrical contact with high durability. For example, additional thin layers may be included between first metallization 286 and highly doped region 284, said layers not being shown here for reasons of clarity. In addition, highly doped area 284 may exhibit, directly underneath metallization 286, a particularly highly doped region which ensures an electrically conductive and non-rectifying contact. First contacting structure 260 thus forms a substrate contact.

In addition, a second metallization 290, which also forms an electrically conductive, low-resistance contact with third semiconductor region 250, is arranged above second semiconductor region 250.

First metallization 284 and second metallization 290 may consist of aluminum, for example. In addition, it is to be noted that first metallization 286 and second metallization 290 may both be partly arranged on isolation layer 280. Preferably, second metallization 290 may be of such a size that second semiconductor region 230 and third semiconductor region 250 are fully sandwiched between second metallization 290 and first semiconductor region 210.

The inventive semiconductor structure 200 may further include a protective layer 294 which is arranged above isolation layer 280 and which may cover, at least in part, also first metallization 286 and second metallization 290.

It shall also be pointed out that first metallization 286 and second metallization 290 may preferably be designed as bond pads, so that it is possible to mount a bonding wire directly at first metallization 286 or at second metallization 290. This requires for protective layer 294 to exhibit a recess in the area of first metallization 286 and of second metallization 290.

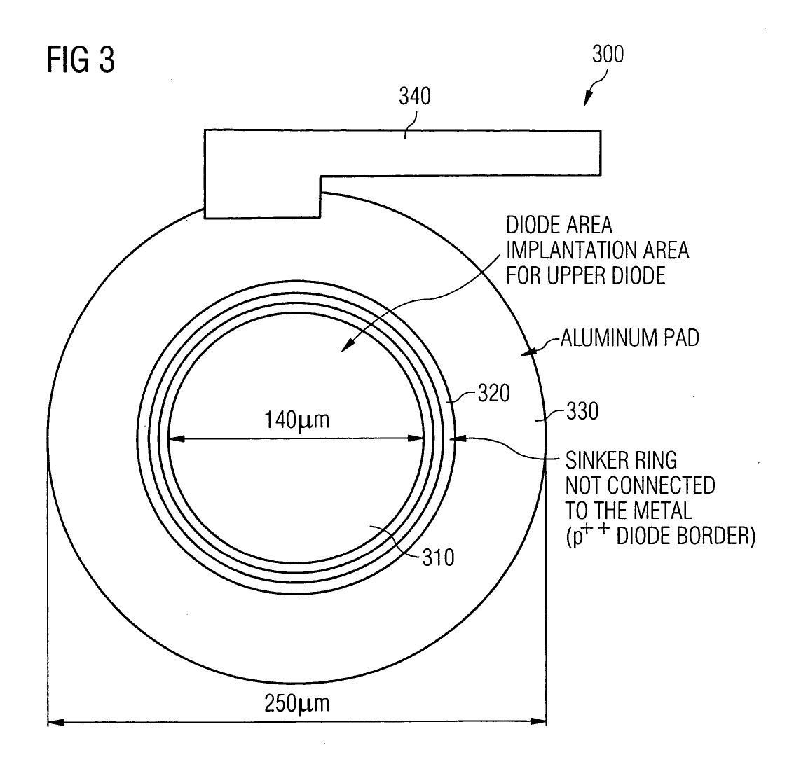

FIG. 3 further shows a graphical representation of manufacturing masks for manufacturing an inventive semiconductor structure 200 in accordance with the second embodiment of the present invention. The graphical representation of FIG. 3 is designated by 300 in its entirety and thus represents a top view of an inventive semiconductor structure 200 in accordance with the second embodiment of the present invention. However, it shall be pointed out here that the graphical representation 300 of FIG. 3 does not show first contacting structure 260, but shows only the actual semiconductor structure consisting of second semiconductor region 230, third semiconductor region 250, isolation structure 224 and second metallization 290.

In the graphical illustration 300, a diode area 310 may be recognized. The diode area 310 here is defined by second contact pad 258 between second semiconductor region 230 and third semiconductor region 250. Thus, diode area 310 is essentially defined by a diffusion mask which is used when third semiconductor region 250 is diffused into second semiconductor region 230. It shall be pointed out here that in the embodiment shown, the diode area 310 is a circular area having a diameter of about 140 μm. In other words, second contact pad 258 between second semiconductor region 230 and third semiconductor region 250 is a circular area having a diameter of about 140 μm. Diode area 310 incidentally forms the implantation area for the upper diode.

A spatial limitation of a semiconductor junction between second semiconductor region 230 and first semiconductor region 210 is defined by isolation structure 224. In the graphical representation 300, that area in which a doping for forming the isolation structure 224 is introduced into semiconductor layer 220 is marked by 320. Area 320 has the shape of an annulus having an interior diameter of about 160 μm and a width of about 6 μm. Area 320 here defines the sinker ring not connected to a metallization, and it may thus be also regarded as a “p⁺⁺diode border”. In other words, first contact pad 254 between first semiconductor region 210 and second semiconductor region 230 is approximately circular in shape and exhibits a diameter of about 160 μm. A diameter of first contact pad 254 thus differs by less than 20% from a diameter of second contact pad 258. Thus, isolation structure 224 is formed by an annular-shaped implanted region of about 6 μm in width.

However, the second metallization 290, which in the graphical representation 300 may be recognized as a circular region 330, has a diameter of about 250 μm and defines an aluminum pad, or aluminum contact.

It shall further be pointed out that isolation structure 224, which is also referred to as “sinker ring” here, is not connected to second metallization 290 in an electrically conductive manner, of course. Rather, isolation structure 224 is electrically isolated from metallization 290, for example by isolation layer 280.

It shall further be pointed out that the graphical representation 300 of FIG. 3 shows further masks which serve, for example, to define the recess in isolation layer 280 and which will not be explained in more detail here. However, it shall be noted that isolation layer 280 is designed such that second metallization 290 exhibits no conductive contact with second semiconductor region 230 and with isolation structure 224.

In addition, graphical representation 300 of FIG. 3 shows part of a supply line 340 designed to connect second metallization 290, i.e. the circular aluminum pad 330, to a further wiring.

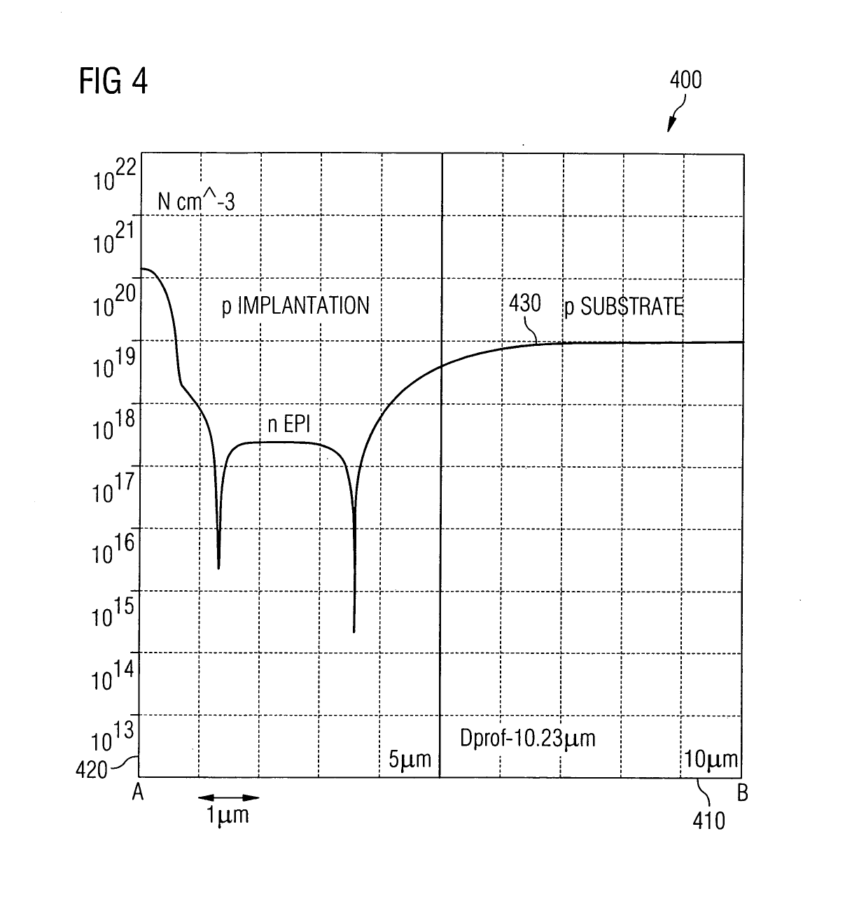

In addition, FIG. 4 shows a doping profile of the inventive semiconductor structure in accordance with the second embodiment of the present invention. The doping profile of FIG. 4 is designated by 400 in its entirety and is taken along a line X, shown in the cross section 200 of FIG. 2. An abscissa 410 here describes an x coordinate, measured from the contact pad between third semiconductor region 250 and second metallization region 290 in the direction of first semiconductor region 210. The amount of a dopant concentration in a range between 10¹² cm⁻³ and 10²² cm⁻³ is plotted on an ordinate 420. Here, a curve 430 describes an amount of a effective dopant concentration as a function of the position plotted on abscissa 410.

In other words, the left-hand side of doping profile 410 describes the doping at a first point A, whereas the right-hand side of the doping profile describes the doping at a second point B. However, it shall be pointed out here that first semiconductor layer 210 preferably forms a substrate, or carrier material, and may therefore be considerably thicker than shown in the doping profile 400. Thus, first semiconductor region 210 may have a thickness ranging between 100 μm and 1000 μm. In accordance with the exemplary doping profile 400, third semiconductor region 250 has a thickness of about 1.3 μm and is diffused into the semiconductor layer 220. The maximum doping concentration in the third semiconductor region 250 is about 2×10²⁰ cm⁻³ and is achieved at the border area between third semiconductor region 250 and second metallization 290. As may be seen from doping profile 400, the doping of third semiconductor region 250 is achieved in two steps. Specifically, a (effective) doping of about 3×10¹⁸ cm⁻³ is doped into third semiconductor region 250, said doping obviously decreasing toward second contact pad 258 between third semiconductor region 250 and second semiconductor region 230. In addition, a second, very high doping is introduced at the top surface of third semiconductor region 250 which adjoins second metallization 290, So as to achieve an ohmic contact between third semiconductor region 250 and second metallization 290.

In that area in which third semiconductor region 250 is diffused into semiconductor layer 220, second semiconductor region 230 has a thickness of about 2.3 μm. Here, the second semiconductor region represents an n-doped region which has been deposited epitactically, and comprises a doping concentration of about 3×10¹⁷ cm−³ and is thus also referred to as “n EPI”. On the other hand, first semiconductor region 210 is formed by a p-doped substrate with a doping concentration of 1×10¹⁹ cm⁻³. The (effective) dopant concentration in the p substrate and/or in the first semiconductor region obviously decreases toward first contact pad 254 between the first semiconductor region and second semiconductor region 230. This is due to diffusion effects during the manufacturing of the inventive semiconductor structure 200, but is also due to the effect of “counter doping”.

Generally it may be stated that the first semiconductor region should preferably have a doping of between 10¹⁸ cm⁻³ and 10²⁰ cm⁻³, measured at a distance of about 2 μm from a boundary area between first semiconductor region 210 and semiconductor layer 220. On the other hand, second semiconductor region 220 should preferably have a doping concentration of between 10¹⁶ cm⁻³ and 10¹⁸ cm⁻³, measured in the center of second semiconductor region 230. However, third semiconductor region 250 should preferably have an average dopant concentration between 10¹⁸ cm⁻³ and 10²¹ cm⁻³. The thickness of first semiconductor region 210 should be at least 2 μm, however it is preferred to use a substrate, for first semiconductor region 210, which also serves as a mechanical carrier material and thus preferably has a thickness of between 100 μm and 1000 μm. A thickness of second semiconductor layer 120 should preferably range between 0.5 μm and 5 μm, so that the inventive semiconductor structure 200 may act as a bipolar transistor with a floating base region. The thickness of third semiconductor region 250 should preferably range between 0.5 μm and 5 μm.

In addition, a doping concentration of isolation structure 224 should preferably range between 10¹⁸ and 10²¹ cm⁻³, just like a doping concentration of highly doped area 224.

The inventive semiconductor structure 200 may change its wide range without deviating from the core idea of the present invention. For example, isolation structure 224 may be realized by a trench which is introduced into semiconductor layer 220 and is filled with an isolating material. Even though this solution requires more technical effort than introducing an annular-shaped doping, particularly advantageous isolating properties may nevertheless be achieved by a trench filled with an isolator. An oxide, e.g. silicon, may serve as an isolator, for example. Other oxides or nitrides known from semiconductor technology may also be used for isolation structure 224.

In addition, first contacting structure 260 may be configured differently. For example, a recess may be introduced into semiconductor layer 220, so that a metallization has a direct contact with first semiconductor region 210. The contacting of first semiconductor region 210 may also be effected from the bottom, i.e. from a surface opposite the contact pad between first semiconductor region 210 and semiconductor layer 220.

In addition, the semiconductor regions may vary in size. Third semiconductor region 250, for example, may be in contact with isolation structure 224 if isolation structure 224 is made from an isolating material (rather than from a doped semiconductor). In addition, metallizations 286 and 290 may vary in size. First metallization 286 may, for example, be larger or smaller than highly doped area 284. Second metallization 290, too, may be larger or smaller, in terms of its area expanse, than second semiconductor region 230, and larger or smaller than third semiconductor region 250. However, it is also very well possible for second semiconductor region 230, third semiconductor region 250 and second metallization 290 to be approximately equal in size in terms of their area, i.e. the areas of the regions mentioned differ by no more than 15%, for example.

In addition, the doping type of all semiconductor regions may be reversed. In other words, first semiconductor region 210 may be highly n-doped, whereas second semiconductor region 230 is lightly p-doped, and third semiconductor region 250, in turn, is highly n-doped. In this case, isolation structure 224 is preferably a highly n-doped, annular area. Also, highly doped area 284 in this case is preferably a highly n-doped area (n⁺⁺).

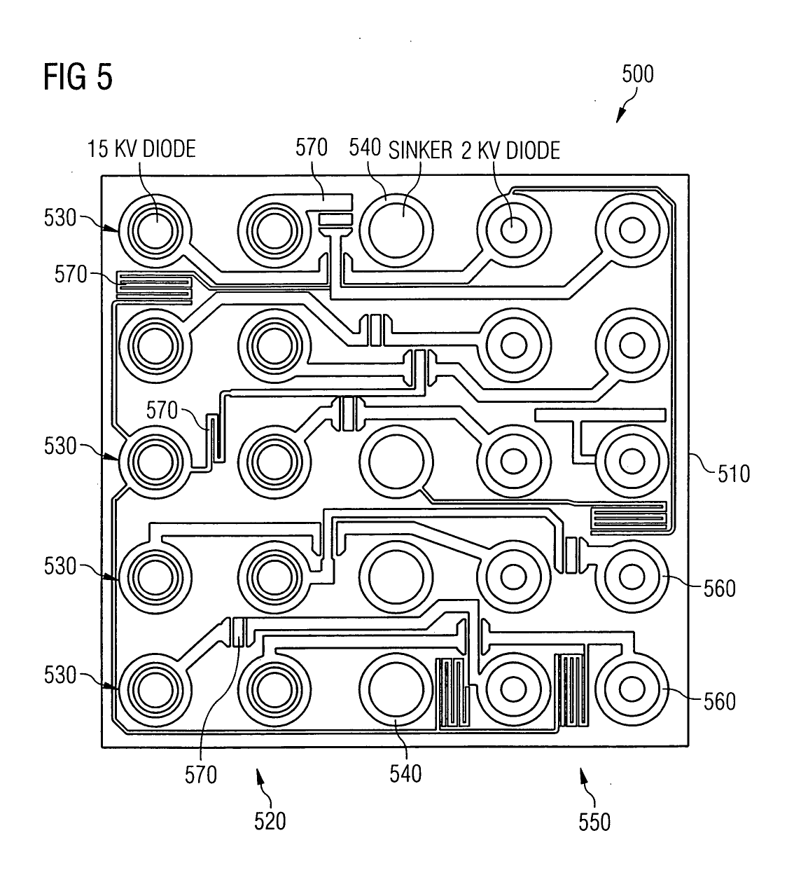

FIG. 5 shows a top view of an inventive overvoltage protection circuit with inventive semiconductor structures in accordance with the second embodiment of the present invention. The overvoltage protection circuit of FIG. 5 is designated by 500 in its entirety. Overvoltage protection circuit 500 here includes a chip 510 which has a plurality of inventive semiconductor structures arranged thereon. A first part 520 of the inventive protection circuit has external contacts designed for connection with an external connection of an electronic device. The external contacts have a contacting structure corresponding to second contacting structure 264 of the inventive semiconductor structure 200 shown in FIG. 2. In other words, the top view of the inventive overvoltage protection circuit 500 shows metallizations corresponding to second metallization 290 of the inventive semiconductor structure 200 shown in FIG. 2. It shall be pointed out here that the first circuit part 520 has ten semiconductor structures 530 contained therein which include essentially a second semiconductor region 230, a third semiconductor region 250, a second metallization 290 as well as an isolation structure 224, respectively. It shall further be pointed out that the ten semiconductor structures 530 of first circuit part 520 share first semiconductor region 210, i.e. the substrate of chip 510. Semiconductor structures 530 further comprise no individually associated contacting structure 260. Rather, chip 510 includes three substrate contacting structures 540 corresponding, in terms of their essential architectures, to the first contacting structure 260 shown in FIG. 2 in each case. In other words, chip 510 shares three substrate contacting structures 540 (also referred to as “sinkers”) for the ten semiconductor structures 530 of the first circuit part. It shall further be noted that the ten semiconductor structures 530 of first circuit part 520 include metallizations 290 adapted to establish a direct connection to a carrier material from which chip 510 may be deposited. For example, metallizations 290 may be designed to be contacted with bonding wires. In addition, metallizations 290 may be designed to establish a conductive contact with a connection bead. For example, metallizations 290 may also be designed for flip-chip technology.

In addition, chip 510 includes a second circuit part 550 including eleven further semiconductor structures 560 which are also referred to as “2 kV diodes”. In terms of their architectures, semiconductor structures 560 may correspond, in turn, to the inventive semiconductor structure 200 shown in FIG. 2, no separate contacting structure 260 being provided, in turn, for first semiconductor region 210. Rather, in the inventive overvoltage protection circuit 500, all semiconductor structures 530, 560 are coupled to the substrate as the first semiconductor region 210, wherein, as has been described above, the substrate is contacted via three substrate contacting structures 540 which correspond to first contacting structure 260. In addition, it shall be noted that preferably one semiconductor structure 530 of first circuit part 520 is connected, via a resistor 570, to a semiconductor structure 560 of second circuit part 550 in each case.

It shall be pointed out in this context that it is preferred to design the semiconductor structures 530 of first circuit part 520 for a dielectric strength of 15 kV, while semiconductor structures 560 of second circuit part 550 are preferably designed for a dielectric strength of 2 kV. Here, the dielectric strength corresponds to an ESD strength and is also described by a so called maximum tolerable voltage between first contacting structure 260 and second contacting structure 264. For this reason, semiconductor structures 530 of the first circuit part are also referred to as “15 kV diodes”, whereas semiconductor structures 560 of second circuit part 550 are referred to as “2 kV diodes”.

The inventive overvoltage protection circuit 500 thus ensures double protection both at first circuit part 520 designed for coupling two external connections of a device, and in second circuit part 550 designed for coupling to internal connections of a device. Thus, the external connections, which are preferably coupled to semiconductor structures 530, are protected against overvoltage pulses having amplitudes of up to 15 kV. Internal connections, which are preferably coupled to semiconductor structures 560 of second circuit part 550, however, are protected against overvoltage pulses having amplitudes of up to 2 kV. The overvoltage pulses occurring at the metallizations and/or connections of semiconductor structures 530 of the first circuit part or of semiconductor structures 560 of second circuit part 550, are drained to the substrate contacting structures 540 preferably coupled to a reference potential. In addition, an increased level of security against overvoltages is ensured by a resistor 570 introduced between semiconductor structures 530 of first circuit part 520, and semiconductor structures 560 of second circuit part 550, respectively.

Generally speaking, it is preferred, incidentally, for at least two inventive semiconductor structures to share the same substrate, i.e. for two semiconductor structures to share the first semiconductor region. In other words, a continuous semiconductor substrate preferably carries at least two inventive semiconductor structures, the semiconductor substrate serving, for both semiconductor structures, as the first semiconductor region 110, 210, and one contacting structure 260 being shared by the at least two inventive semiconductor structures.

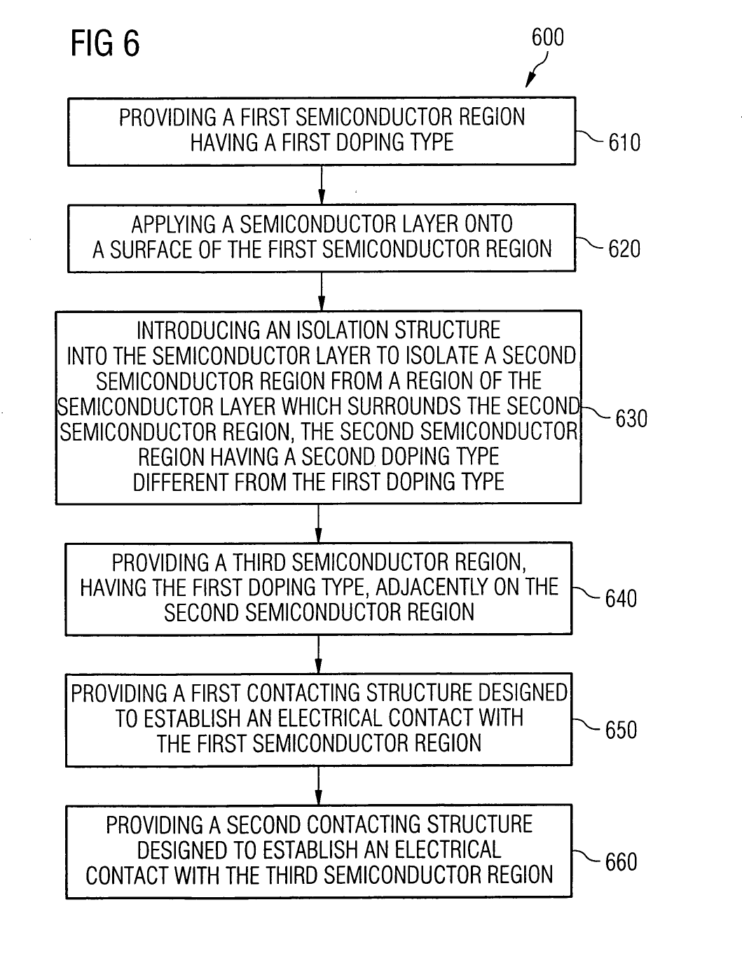

FIG. 6 shows a flow chart of an inventive method for manufacturing an inventive semiconductor structure. The flow chart of FIG. 6 is designated by 600 in its entirety.

The inventive method includes a first step 610 of providing a first semiconductor region 110; 210 comprising a first doping type. In a second step 620, a semiconductor layer 120, 220 is deposited onto a surface of first semiconductor region 110, 210. In a third step 630, an isolation structure 124, 224 is then introduced into semiconductor layer 120, 220 SO as to electrically isolate a second semiconductor region 130, 230 from a region 140, 240 of semiconductor layer 120, 220 which surrounds second semiconductor region 130, 230. Second semiconductor region 130, 230 has a second doping type different from the first doping type. In a fourth step 640, a third semiconductor region 150, 250 is then provided which has the first doping type and is adjacent to second semiconductor region 130, 230. In a fifth step 650, a first contacting structure 160, 260 is provided which is designed to establish an electrical contact with first semiconductor region 110, 210. In a sixth step 660, a second contacting structure 164, 264 is further provided which is designed to establish an electrical contact with third semiconductor region 150, 250. The establishment is effected such that third semiconductor region 150, 250 adjoins semiconductor layer 120, 220 only within a region limited by isolation structure 124, 224. In addition, it shall be pointed out that first semiconductor region 110, 210 is more highly doped than second semiconductor region 130, 230, and that third semiconductor region 150, 250 is more highly doped than second semiconductor region 130, 230.

In addition, it shall be pointed out that isolation structure 124; 224 may preferably be produced by introducing a highly doped area into semiconductor layer 120, 220, and that the provision of first contacting structure 160 may include introducing a second highly doped area 284 into semiconductor layer 120, 220. In addition, it is preferred to simultaneously perform the provisions of the isolation structure 124, 224 and of the second highly doped area 284, i.e. to perform these provisions within a semiconductor-technology processing step.

In addition, the isolation structure may be introduced into the semiconductor layer by means of ion implantation, so that borders of the isolation structure extend almost vertically to a contact pad between the first semiconductor region and the semiconductor layer.

Also, it shall be pointed out that the inventive manufacturing method may also include providing or producing all further features which have been described with regard to the inventive device. The geometry and doping parameters used in the manufacturing method may also be selected as has been described above with regard thereto.

Thus it may be stated, in summary, that the present invention achieves particular advantages in that a pnp structure is arranged vertically, the lower pn junction being formed by p⁺ substrate and n epitaxy, and the upper pn junction being formed by n epitaxy and a p⁺ diffusion region. As with a lateral pnp transistor with a floating base, here, too, the current is largely transported by majority charge carriers. A base substrate diode is spatially defined by an annular p-doped sinker which electrically isolates the base from the surroundings.

Since a sinker implantation is required for substrate contacting anyway, no further process step needs to be performed, in this technology, for producing the limitation sinker, and thus for lateral definition of the diode epitaxy substrate. Alternatively, the diode mentioned may also be limited by an oxide-filled trench, which, however, represents substantial additional effort.

The sequence of the dopant regions may also be inverted as compared to the arrangement shown. An npn arrangement here has the advantage that a trench capacitor with an n trough may be integrated without danger to latch-up.

The vertical arrangement may be completely placed underneath a contact. This saves surface area on the chip for other passive elements such as resistors, coils or capacitors. With the integrated circuits packaged at the wafer level, which are employed in large amounts in the mobile radio field—where about 30% of the chip area is covered by contacts—some applications require that the inventive semiconductor structure and/or the diode be arranged underneath the contacts.

The two-dimensional design of the pnp structure exhibits a better ESD-strength to capacitance ratio (also referred to as ESD/C(OV) ratio) while having the same ESD strength, than a lateral pnp structure having a higher level of stray capacitance because of the finger arrangement. In addition, with the conventional finger structure, it is mainly the edge which contributes to the current conductivity in the breakdown, whereas with the inventive structure described, the entire device surface may receive current in an approximately even manner.

With the inventive vertical 14 V pnp transistors designed for a breakdown voltage of 14 volt, one has measured an ESD strength of 21 kV and a capacitance at a voltage of 0 volt, also referred to as C (0V), of 4 pF. With lateral 14 V pnp transistors designed for a breakdown voltage of 14 V, however, one has measured an ESD strength of 17 kV and a capacitance C (0V) of 10 pF at a voltage of 0 volt. Compared to lateral np diodes, the benefit of the inventive semiconductor structure with regard to the ESD/C(0V) ratio is even more pronounced. Specifically, with conventional lateral np diodes, a capacitance of 17.5 pF comes with an ESD strength of only 6 kV. Even though the values of the conventional lateral structures mentioned were measured at less than fully optimized geometries and/or layouts, the figures mentioned nevertheless clearly indicate the advantage of the inventive structure with regard to the ESD−/C(0V) ratio. Specifically, with regard to the ESD/C(0V) ratio, a vertical structure is always advantageous over conventional lateral structures due to the lower level of stray capacitance.

FIG. 5 shows an inventive overvoltage protection circuit for mobile telephones having the functions of signal filtering and ESD protection of integrated circuits (ICs) at connection contacts for memory cards. Here, nine signal lines are led through the chip 510. In addition, 15 resistors 570 are integrated on chip 510. The signal lines have one side connected to an exterior contact of the mobile phone, respectively, the exterior contacts being arranged on first circuit part 520. All of the exterior contacts are protected by one 15 kV ESD protection structure each. All other pins are protected against 2 kV pulses.

It shall also be pointed out that chip 510 uses a reduced contact raster of 400 μm. Thus, the surface area on the chip is already very scarce for electrical elements and for guiding conductive traces. It would not be possible to integrate lateral diodes here. In addition, it would also be very difficult, because of the high capacitance of conventional lateral structures, to adhere to the maximally admissible capacitance of 20 pF per line. However, using inventive semiconductor structures 530, 560, sufficient protection against overvoltages and/or electrostatic discharges (ESD protection) may be ensured even at the cramped spatial conditions mentioned, a maximally admissible capacitance of 20 pF per line not being exceeded. In other words, utilization of an inventive vertical semiconductor structure and/or ESD protection structure in an inventive overvoltage protection circuit 500 entails substantial advantages and enables, the very realization of an inventive overvoltage protection circuit 500 within the smallest space possible and at low levels of capacitance.

It may thus be stated, in summary, that the present invention provides a semiconductor structure as well as an overvoltage protection circuit which enables dissipation of an overvoltage pulse in the order of 15 kV at a low self-capacitance and low space requirements. The inventive semiconductor structure may be realized in a technologically advantageous manner and enables production of an inventive overvoltage protection circuit at low cost.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A semiconductor structure for draining an overvoltage pulse, comprising:
a first semiconductor region having a first doping type;
a semiconductor layer arranged adjacent the first semiconductor region, the semiconductor layer including an isolation structure configured to electrically isolate a second semiconductor region from a surrounding region, the second semiconductor region having a second doping type;
a third semiconductor region having the first doping type arranged adjacent the second semiconductor region and disposed within an area limited by the isolation structure;
a first contacting structure configured to provide an electrical contact with the first semiconductor region; and
a second contacting structure configured to provide an electrical contact with the third semiconductor region;
wherein the first and second semiconductor regions are more highly doped than the second semiconductor region.

2. The semiconductor structure as claimed in claim 1, wherein the semiconductor structure comprises a vertical bipolar transistor, the first semiconductor region being a collector region of the vertical bipolar transistor, the second semiconductor region being a base region of the vertical bipolar transistor, and the third semiconductor region being an emitter region of the vertical bipolar transistor.

3. The semiconductor structure as claimed in claim 1, wherein the semiconductor structure comprises a vertical bipolar transistor, the first semiconductor region representing being emitter region of the vertical bipolar transistor, the second semiconductor region being a base region of the vertical bipolar transistor, and the third semiconductor region being a collector region of the vertical bipolar transistor.

4. The semiconductor structure as claimed in claim 2, the semiconductor structure comprising a vertical bipolar transistor with a floating base region.

5. The semiconductor structure as claimed in claim 1, wherein the second semiconductor region is configured to float.

6. The semiconductor structure as claimed in claim 1, wherein the second semiconductor region is configured to be electrically isolated from all regions surrounding the second semiconductor region when a voltage between the first contacting structure and the second contacting structure is smaller than a predefined breakdown voltage.

7. The semiconductor structure as claimed in claim 6, wherein the semiconductor structure is configured such that an avalanche breakdown occurs in a space-charge region between the first semiconductor region and the second semiconductor region when the voltage between the first contacting structure and the second contacting structure is higher than the predefined breakdown voltage.

8. The semiconductor structure as claimed in claim 6, wherein the semiconductor structure is configured such that an avalanche breakdown occurs in a space-charge region between the second semiconductor region and the third semiconductor region when the voltage between the first contacting structure and the second contacting structure is higher than the predefined breakdown voltage.

9. The semiconductor structure as claimed in claim 6, wherein the semiconductor structure is configured to conduct a current between the first contacting structure and the second contacting structure through the second semiconductor region without the semiconductor structure being destroyed when the voltage between the first contacting structure and the second contacting structure is higher than the predefined breakdown voltage and smaller than a maximum tolerable voltage.

10. The semiconductor structure as claimed in claim 1, wherein the second semiconductor region is electrically coupled to the first and third semiconductor regions via a first pn junction and a second pn junction, respectively, the first pn junction and the second pn junction being connected in anti-series between the first contacting structure and the second contacting structure.

11. The semiconductor structure as claimed in claim 1, wherein the second semiconductor region is fully enclosed by the first semiconductor region, the third semiconductor region and the isolation structure.

12. The semiconductor structure as claimed in claim 1, wherein the second semiconductor region is fully enclosed by the first semiconductor region, the third semiconductor region, the isolation structure and an isolating layer, the isolating layer being arranged on the semiconductor layer such that it covers a surface of the second semiconductor region opposite the first semiconductor region in an area surrounding a contact pad between the second semiconductor region and the third semiconductor region.

13. The semiconductor structure as claimed in claim 1, wherein the isolation structure is configured to electrically isolate the second semiconductor region, by a space-charge region, from the region surrounding the second semiconductor region.

14. The semiconductor structure as claimed in claim 1, wherein the isolation structure comprises a doped area of the first doping type extending through the semiconductor layer from a first surface, where the semiconductor layer adjoins the first semiconductor region, to a second surface of the semiconductor layer opposite the first surface.

15. The semiconductor structure as claimed in claim 14, wherein the doped area is more highly doped than the second semiconductor region.

16. The semiconductor structure as claimed in claim 1, wherein the isolation structure comprises a trench, the trench extending through the semiconductor layer from a first surface, where the semiconductor layer adjoins the first semiconductor region, to a second surface of the semiconductor layer opposite the first surface, the trench being filled with an electrically isolating material.

17. The semiconductor structure as claimed in claim 1, wherein the isolation structure is configured to enclose the second semiconductor region within the semiconductor layer.

18. The semiconductor structure as claimed in claim 17, wherein the isolation structure is configured to enclose the second semiconductor region substantially in the shape of a circle.

19. The semiconductor structure as claimed in claim 1, wherein the first contacting structure includes a doped area of the first doping type configured to contact the first semiconductor region in a conducting manner, the first contacting structure extending from a first surface of the semiconductor layer, where the semiconductor layer contacts the first semiconductor region, to a second surface of the semiconductor layer opposite the first surface.

20. The semiconductor structure as claimed in claim 19, wherein the isolation structure comprises a doped area of the first doping type extending through the semiconductor layer from a first surface, where the semiconductor layer contacts the first semiconductor region, to a second surface of the semiconductor layer opposite the first surface,
the doped area of the isolation structure, and the doped area of the first contacting structure being arranged at a spatial distance from each other and manufactured in the same manufacturing step.

21. The semiconductor structure as claimed in claim 1, wherein the second contacting structure includes a metallization electrically contacting the third semiconductor region and configured such that the second semiconductor region and the third semiconductor region are located fully between the metallization and the first semiconductor region.

22. The semiconductor structure as claimed in claim 1, wherein the third semiconductor region is diffused into the semiconductor layer at a surface of the semiconductor layer opposite a contact pad between the semiconductor layer and the first semiconductor region.

23. The semiconductor structure as claimed in claim 1, wherein the first semiconductor region comprises a semiconductor material configured to act as a mechanical carrier for the semiconductor structure.

24. The semiconductor structure as claimed in claim 1, wherein the semiconductor layer comprises an epitactic layer.

25. The semiconductor structure as claimed in claim 1, wherein the semiconductor structure is configured such that a current density varies by less than 50% across a contact pad between the first semiconductor region and the second semiconductor region when an avalanche breakdown occurs at a pn junction between the first semiconductor region and the second semiconductor region.

26. The semiconductor structure as claimed in claim 1, wherein a dielectric strength between the first contacting structure and the second contacting structure is greater than approximately 10 kV.

27. The semiconductor structure as claimed in claim 1, wherein a current flow through the second semiconductor region is configured to drain an the overvoltage pulse between the first contacting structure and the second contacting structure.

28. The semiconductor structure as claimed in claim 1, wherein the second semiconductor region comprises a substantially cylinder disc.

29. The semiconductor structure as claimed in claim 1, wherein the second semiconductor region has a doping with an effective dopant concentration in a range between approximately 10¹⁶ cm⁻³ and 10¹⁸ cm⁻³.

30. The semiconductor structure as claimed in claim 1, wherein the first semiconductor region has a doping with an effective dopant concentration in a range between approximately 10¹⁸ cm⁻³ and 10²⁰ cm⁻³.

31. The semiconductor structure as claimed in claim 1, wherein the third semiconductor region has a doping with an effective dopant concentration in a range between approximately 10¹⁸ cm⁻³ and 10²¹ cm⁻³.

32. The semiconductor structure as claimed in claim 1, wherein the second semiconductor region has a thickness in a range between approximately 0.5 μm and 5 μm.

33. The semiconductor structure as claimed in claim 1, wherein the second semiconductor region has a diameter in a range between approximately 30 μm and 500 μm.

34. The semiconductor structure as claimed in claim 1, further comprising:
a further isolation structure introduced into the semiconductor layer to electrically isolate a fourth semiconductor region from a region of the semiconductor layer which surrounds the fourth semiconductor region, the fourth semiconductor region having the second doping type;
a fifth semiconductor region having the first doping type and being arranged adjacent the fourth semiconductor region within an area limited by the further isolation structure;
a third contacting structure configured to provide an electrical contact between the fourth semiconductor region and the fifth semiconductor region; and
wherein the first and fifth semiconductor regions are more highly doped than the fourth semiconductor region.

35. A method for manufacturing a semiconductor structure, comprising:
providing a first semiconductor region having a first doping type;
applying a semiconductor layer onto a surface of the first semiconductor region;
introducing an isolation structure into the semiconductor layer to electrically isolate a second semiconductor region from a region of the semiconductor layer which surrounds the second semiconductor region, the second semiconductor region having a second doping type which is different rom the first doping type;
providing a third semiconductor region, having the first doping type, adjacently on the second semiconductor region;
providing a first contacting structure formed to establish an electrical contact with the first semiconductor region; and
providing a second contacting structure formed to establish an electrical contact with the third semiconductor region, the third semiconductor region adjoining the semiconductor layer only within an area limited by the isolation structure;
wherein the first and third semiconductor regions are more highly doped than the second semiconductor region.

36. The method as claimed in claim 35, wherein introducing the isolation structure into the semiconductor layer includes:
producing a first highly doped area in the semiconductor layer.

37. The method as claimed in claim 35, wherein providing the first contacting structure includes:
producing a second highly doped area in the semiconductor layer.

38. The method as claimed in claim 35, wherein introducing the isolation structure into the semiconductor layer includes:
producing a first highly doped area in the semiconductor layer; and
wherein providing the first contacting structure includes:
producing a second highly doped area in the semiconductor layer;
wherein the producing of the first highly doped area and the producing of the second highly doped area are performed substantially simultaneously.
